(19) United States
(12) Patent Application Publication
(10) Pub. No.: US 2006/0239800 A1
(43) Pub. Date: Oct. 26, 2006

(54) Pulsed DC and RF physical vapor deposition cluster tool

(76) Inventors: Roger Hamamjy, San Jose, CA (US); Kuo-Wei Chang, Sunnyvale, CA (US); Jong-Won Lee, San Francisco, CA (US)

Correspondence Address: TROP PRUNER & HU, PC, 1616 S. VOSS ROAD, SUITE 750, HOUSTON, TX, 77057-2631, US

(21) Appl. No.: 11/114,261

(22) Filed: Apr. 26, 2005

(51) Int. Cl. H01L 21/677

(52) U.S. Cl. 414/217

(57) ABSTRACT

Radio frequency sputtering of high resistance films may be achieved in a cluster tool. Suitable radio frequency isolation may be utilized to enable RF sputtering in an environment which may sensitive to radio frequency energy.

### BACKGROUND

This invention relates generally to cluster tools for etching and depositing layers on semiconductor wafers.

A cluster tool is a robot operated tool which includes a plurality of processing chambers for etching and deposition. One or more robots situated centrally relative to the processing chambers are responsible for transferring the wafers from chamber to chamber for processing.

Commonly, DC sputtering or physical vapor deposition may be implemented in one or more of those chambers. However, such sputtering may not be successful in depositing relatively high resistance films such as chalcogenide materials.

Thus, there is a need for other ways to deposit physical vapor deposition layers in cluster tools.

### BRIEF DESCRIPTION OF THE DRAWINGS

FIG. 1 is a depiction of a physical vapor deposition chamber in accordance with one embodiment of the present invention;

FIG. 2 is an enlarged depiction of a portion of the wafer clamp shown in FIG. 1 in accordance with one embodiment of the present invention; and

FIG. 3 is a top plan view of a cluster tool in accordance with one embodiment of the present invention.

### DETAILED DESCRIPTION

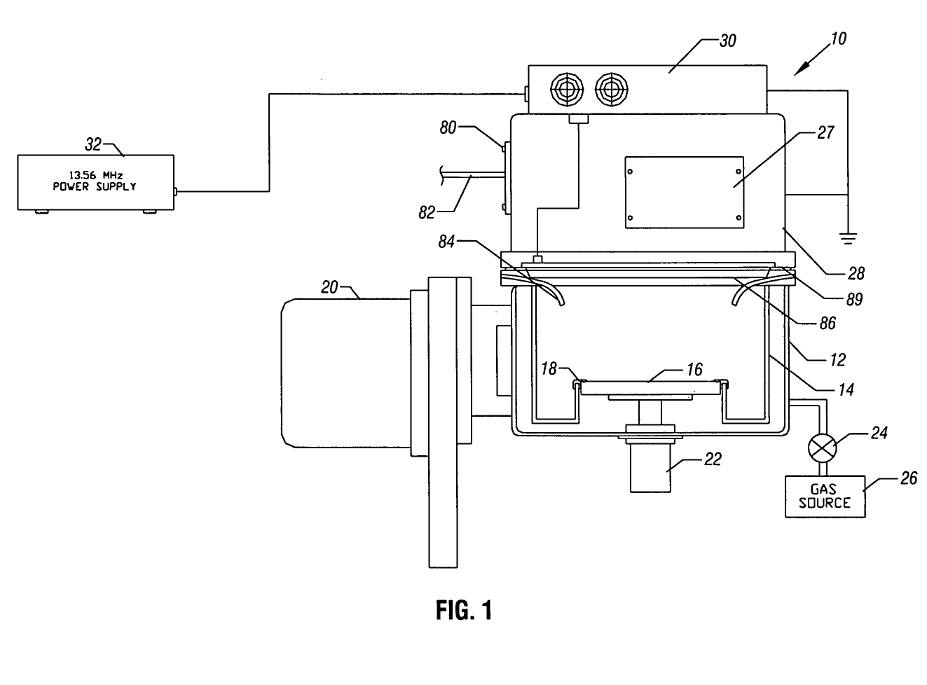

Referring to FIG. 1, a radio frequency (RF) and pulsed direct current (DC) physical vapor deposition (PVD) reactor 10 includes a vacuum chamber 12. In some embodiments, the vacuum chamber 12 may be grounded and may be formed of metal. A controller 22 controls the power supplies and the mass flow controller 24. The mass flow controller 24 is responsible for inletting a gas source 26 to the vacuum chamber 12. The gas source 26 may be a noble gas such as argon.

Inside the chamber 12 is a grounded shield 14. The grounded shield 14 is coupled to a wafer clamp 18. The wafer clamp 18 clamps a wafer (not shown in FIG. 1) on to a pedestal electrode 16. The electrode 16 may be coupled to a bias potential controlled by the controller 22 in some embodiments.

Also contained within the vacuum chamber 12 may be a floating shield 84. Finally, at the top of the chamber 12 is the target 86 which is made of the material to be sputtered on the wafer mounted on the pedestal electrode 16 by the clamps 18.

The vacuum within the chamber 12 may be established by cryopump 20 which communicates through a port (not shown) with the chamber 12. The cryopump 20 maintains a low pressure within the chamber 12.

The DC magnetron and radio frequency generator 28 may include a lid cover 27 made of metal, such a aluminum, instead of plastic for better RF shielding to the source. Also, the access plate 80, for communication connections, may be made of a metal, such as aluminum, to isolate RF power from traveling on communication lines 82. Finally, a metal plate 89 may be located between the target 86 and the generator 28. The plate 89 may be formed of aluminum. The plate 89 may enable better source grounding.

Over the generator 28 may be situated a radio frequency matching circuit 30. The circuit 30 balances out the radio frequency energy from the generator to the chamber load. The RF matching circuit 30 enables the tuning of the RF power supply to the chamber 12. The matching circuit 30 is coupled to a radio frequency power supply 32.

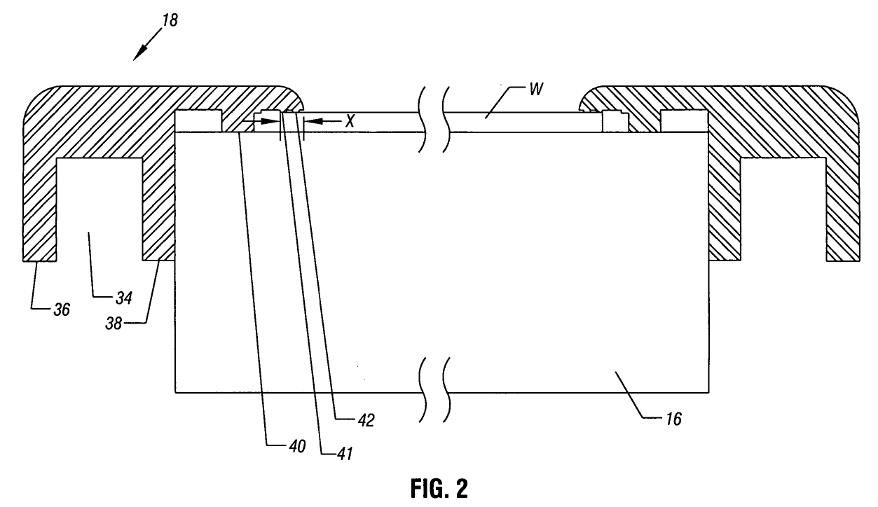

Referring to FIG. 2, the clamp ring 18 includes a pair of downwardly extending arms 38 and 36 which engage, between them the grounded shield 14. An arm 40 extends transversely thereto and is useful for securing the wafer “W” in position on the pedestal electrode 16. The arm 40 includes a pair of spaced prongs 41 and 42. The outer prong 42 is spaced from the innermost edge 43 of the clamp ring 14 by a distance X.

The clamp ring 18 may have an edge exclusion, indicated by the distance X, of 6 millimeters in some embodiments of the present invention. Such an edge exclusion results in minimal contact with the edge of the wafer W. Also, an increased edge exclusion may protect more surface area to prevent cross contamination in the RF physical vapor deposition environment.

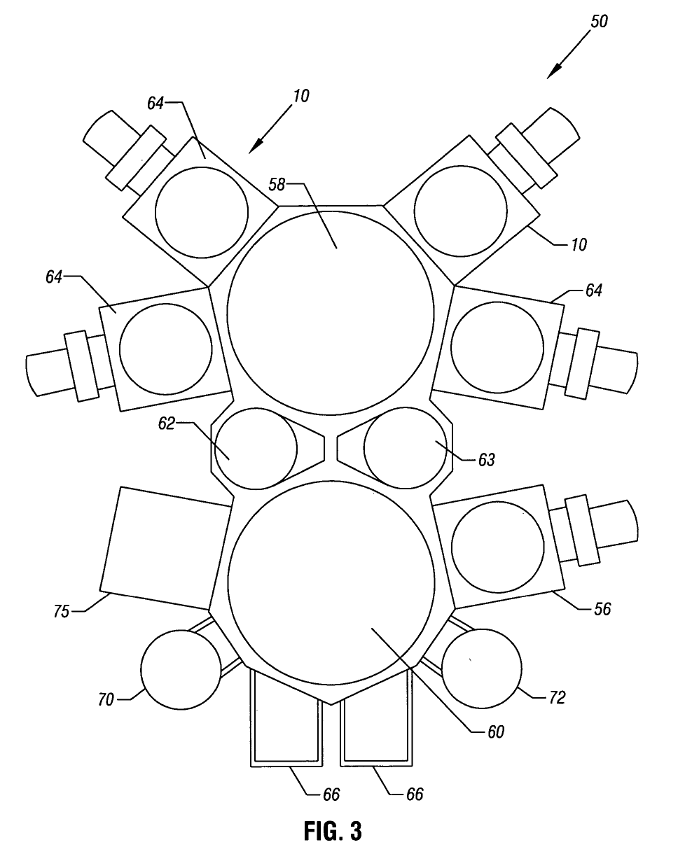

Referring to FIG. 3, a staged-vacuum wafer processing cluster tool 50 may include the reactor 10. A plurality of other chambers 64 may be situated around a transfer robot chamber 58 which includes a robot therein. The robot contained within the chamber 58 transfers wafers between each of the chambers 64 surrounding it and the chamber 10. The robot in the chamber 58 may receive wafers from the treatment chamber 62 and may pass wafers outwardly through the cool down treatment chamber 63. Each of the chambers 64 may be capable of processing the wafer in a different fabrication step. In some cases, each of the chambers may be able to implement one or more of the steps involved in physical vapor deposition.

The robot buffer chamber 60 also includes a robot. That robot may receive wafers from a load lock chamber 66, and transfer them to different stations surrounding the robot buffer chamber 60 or to the treatment chamber 62 for transfer to the transfer robot chamber 58. For example, the chamber 75 may be a pre-clean chamber and the chamber 56 may provide a barrier chemical vapor deposition chamber. The chambers 70 and 72 may be used for degassing and orientation.

Thus, the robot in the robot buffer chamber 60 grabs a wafer from a load lock chamber 66 and transports the wafer to chambers 70, 72 for degassing and orientation. From there the robot in the chamber 60 transfers the wafer to chamber 56 for chemical vapor deposition barrier layer formation in some embodiments of the present invention. Then, the wafer may be transferred to the pre-clean chamber 75.

Finally, the wafer may be transferred by the robot in the robot buffer chamber 60 to the treatment chamber 62 for transfer to the robot chamber 58. From there, various physical vapor deposition (or other steps) may be completed, including the RF or pulsed DC deposition of highly resistive layers in the chamber 10. Once the processing is done, the robot in the chamber 58 transfers the wafer to the cool down treatment chamber 63. From there, it can be accessed by the robot buffer chamber 60 robot and transferred out of the cluster tool 50 through a load lock chamber 66.

In some embodiments of the present invention, the reactor 10 may RF sputter deposit more highly resistive films, such as chalcogenide films. However, the same chamber may also be utilized for pulsed direct current sputtering as well. Because the RF power source is isolated from the rest of the components in the tool 50, RF interference with other chambers and with computer cluster tool 50 controllers that control the robots and other RF sensitive elements may be reduced.

In particular, better RF shielding for the source may be provided, RF power may be isolated from traveling on communication lines, and better source grounding may be achieved. As a result, in some embodiments of the present invention, RF sputtering may be implemented in a cluster tool despite the sensitivity of other components in the cluster tool to the radio frequency power.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
performing radio frequency sputtering in a cluster tool.

2. The method of claim 1 including providing a chemical vapor deposition chamber in a cluster tool for radio frequency and pulsed direct current sputtering.

3. The method of claim 1 including depositing a chalcogenide material by radio frequency sputtering.

4. The method of claim 1 including providing a metal lid cover over a radio frequency generator of a radio frequency deposition chamber.

5. The method of claim 1 including providing a metal access plate for communication connections to a radio frequency generator to isolate radio frequency power from traveling on communication lines.

6. The method of claim 1 including providing a metal plate between a sputtering target and a radio frequency generator to enable better source grounding.

7. The method of claim 1 including providing a clamp ring with an edge exclusion of approximately six millimeters.

8. A cluster tool comprising:
a plurality of processing chambers, including a radio frequency sputter deposition chamber; and
a robot chamber to transfer wafers between said chambers

9. The tool of claim 8 wherein said sputter deposition chamber includes a radio frequency and pulsed direct current generator.

10. The tool of claim 8 including a radio frequency generator, said radio frequency generator covered by a housing, said housing including a metal lid cover.

11. The tool of claim 10 wherein said housing includes a communication line port and a metal cover for said communication line port.

12. The tool of claim 8 wherein said tool includes a radio frequency generator housing, a target, and a metal plate for grounding, said metal plate between said target and said housing.

13. The tool of claim 8 including a wafer clamp ring, said wafer clamp ring having an edge exclusion of approximately 6 mm.

14. A sputter deposition chamber for a cluster tool comprising:
a vacuum chamber;
a matching network mounted on said vacuum chamber; and
a housing over said radio frequency generator, said housing including a metal lid cover.

15. The chamber of claim 14 wherein said housing includes a communication line port and a metal cover for said communication line port.

16. The chamber of claim 14 wherein said vacuum chamber includes a sputter target, a metal plate being positioned between said generator and said vacuum chamber, said metal plate to facilitate grounding.

17. The chamber of claim 14 wherein said generator includes a radio frequency and a direct current generator.
